(19) United States
(12) Patent Application Publication
(10) Pub. No.: US 2008/0265311 A1
(43) Pub. Date: Oct. 30, 2008

(54) VERTICAL TRANSISTOR AND METHOD FOR PREPARING THE SAME

(75) Inventors: Ming Tang, Hualien City (TW); Frank Chen, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/756,529

(22) Filed: May 31, 2007

(30) Foreign Application Priority Data
Apr. 25, 2007 (TW) 096114534

(51) Int. Cl. H01L 21/336; H01L 29/78

(52) U.S. Cl. 257/328; 438/268; 257/E29.262; 257/E21.41

(57) ABSTRACT

A vertical transistor comprises a substrate having a step structure, two doped regions positioned in the substrate at the two sides of the step structure, and a carrier channel positioned in the substrate between the two doped regions, wherein the step structure includes an inclined edge and the width of the carrier channel at the inclined edge is larger than the width of the doped regions. The step structure comprises two non-rectangular surfaces, such as the trapezoid or triangular surfaces, and a rectangular surface. The non-rectangular surfaces connect to the doped regions, and the rectangular surface is perpendicular to the non-rectangular surface.

### BACKGROUND OF THE INVENTION

(A) Field of the Invention

The present invention relates to a vertical transistor and a method for preparing the same, and more particularly, to a vertical transistor having an increased channel length and width and a method for preparing the same.

(B) Description of the Related Art

FIG. 1 illustrates a metal-oxide-semiconductor field effect transistor (MOSFET) 10 according to the prior art. The transistor 10 is an important basic electronic device including a semiconductor substrate 12, a gate oxide layer 14, a conductive metal layer 16 serving as the gate of the transistor 10, two doped regions 18 serving as the source and the drain in the semiconductor substrate 12, and a carrier channel positioned between the two doped regions. The transistor 10 may further include a nitride spacer 22 positioned on the sidewall of the conductive metal layer 16 for isolating the conductive metal layer 16 from other electronic devices on the semiconductor substrate 12.

The length of the carrier channel 22 is equal to the width of the conductive metal layer 16. As semiconductor fabrication technology continues to improve, sizes of electronic devices are reduced, and the width and the length of the carrier channel 22 also decrease correspondingly. The decreasing width and length of the carrier channel 22 results in a serious interaction between the two doped regions 18 and a carrier channel 22 in the semiconductor substrate 12 under the gate oxide layer 14 such that the ability of the conductive metal layer 16 to control the switching operation of the carrier channel 24 is reduced, i.e., causes the so-called short channel effect, which impedes the functioning of the transistor 10.

FIG. 2 and FIG. 3 illustrate a side view and a top view, respectively, of a vertical transistor 30 according to the prior art. The vertical transistor has been widely used to solve the short channel effect, and includes a substrate 32 with a step structure 34, a gate oxide layer 36 positioned on the step structure 34, a conductive layer 38 serving the gate positioned on the gate oxide layer 36, two doped regions 40 serving as the source and the drain positioned in the substrate 32 at two sides of the conductive layer 38, and a carrier channel 42 positioned in the substrate 32 between the two doped regions 40.

The length of the carrier channel 42 is the sum of the height (Hs) and the width (Ws) of the step structure 34, i.e., the length of the carrier channel 42 is increased by the height (Hs) of the step structure 34 without increasing the occupied area of the vertical transistor 30, and the short channel effect is solved. However, the width of the vertical transistor 30 is not increased, as shown in FIG. 3. In other words, the vertical transistor 30 cannot solve the reducing problems of the drain current and the driving ability due to the decreased width of the carrier channel 42 as the size of the transistor is reduced.

In summary, the vertical transistor 30 with step structure 34 can increase the length of the carrier channel 42 to solve the short channel effect, but cannot increase the width of the carrier channel 42 to solve the reducing problems of the drain current or driving ability.

### SUMMARY OF THE INVENTION

One aspect of the present invention provides a vertical transistor having an increased channel length and width and a method for preparing the same.

A vertical transistor according to this aspect of the present invention comprises a substrate having a step structure, two doped regions positioned in the substrate at the two sides of the step structure, and a carrier channel positioned in the substrate between the two doped regions, wherein the step structure includes an inclined edge and the width of the carrier channel at the inclined edge is larger than the width of the doped regions.

Another aspect of the present invention provides a method for preparing a vertical transistor comprising the steps of forming a non-rectangular mask layer on a substrate, etching the substrate by using the non-rectangular mask layer as an etching mask to form a step structure, performing a thermal oxidation process to form a gate oxide layer on the step structure and forming a conductive layer on the gate oxide layer.

The prior art can increase the length of the carrier channel to solve the short channel effect, but cannot increase the width of the carrier channel. In contrast, the vertical transistor of the present invention increases not only the length but also the width of the carrier channel.

### BRIEF DESCRIPTION OF THE DRAWINGS

The objectives and advantages of the present invention will become apparent upon reading the following description and upon reference to the accompanying drawings in which:

FIG. 1 illustrates a metal-oxide-semiconductor field effect transistor (MOSFET) according to the prior art;

FIG. 2 and FIG. 3 illustrate a side view and a top view of a vertical transistor according to the prior art;

FIG. 4 to FIG. 6 illustrate a vertical transistor according to one embodiment of the present invention;

FIG. 7 compares the current-voltage property of the conventional vertical transistor with that of the present vertical transistor;

FIG. 8 and FIG. 9 illustrate a vertical transistor according to another embodiment of the present invention; and

FIG. 10 to FIG. 16 illustrate a method for preparing a vertical transistor.

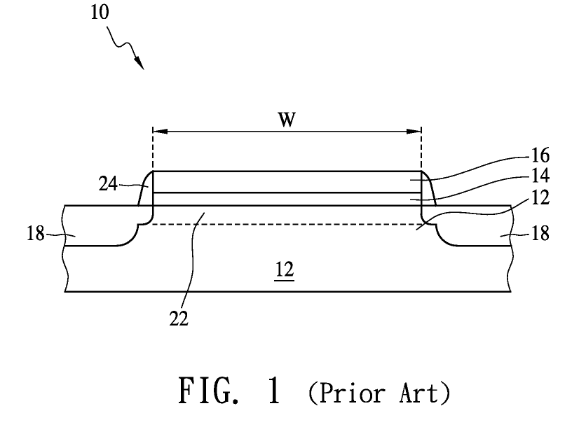

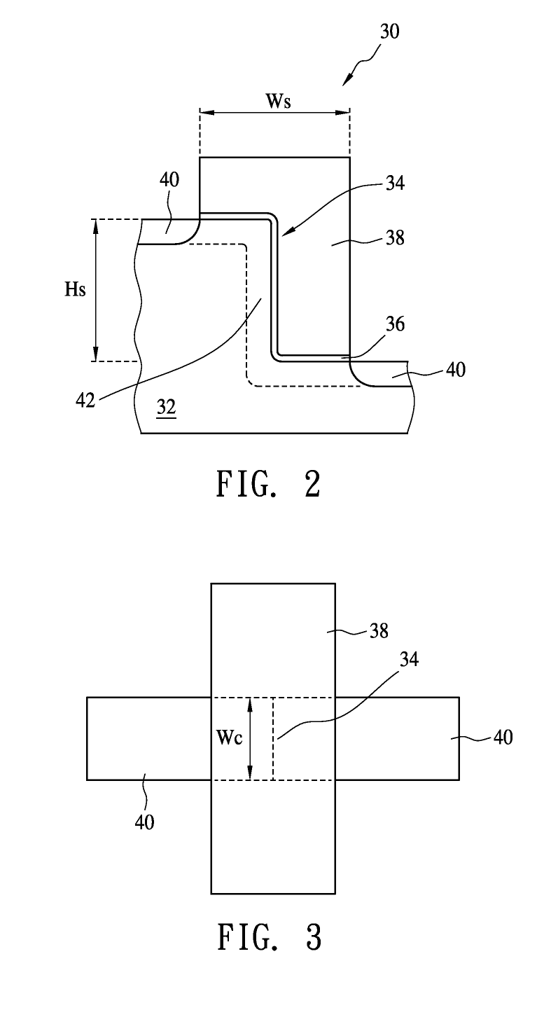

### DETAILED DESCRIPTION OF THE INVENTION

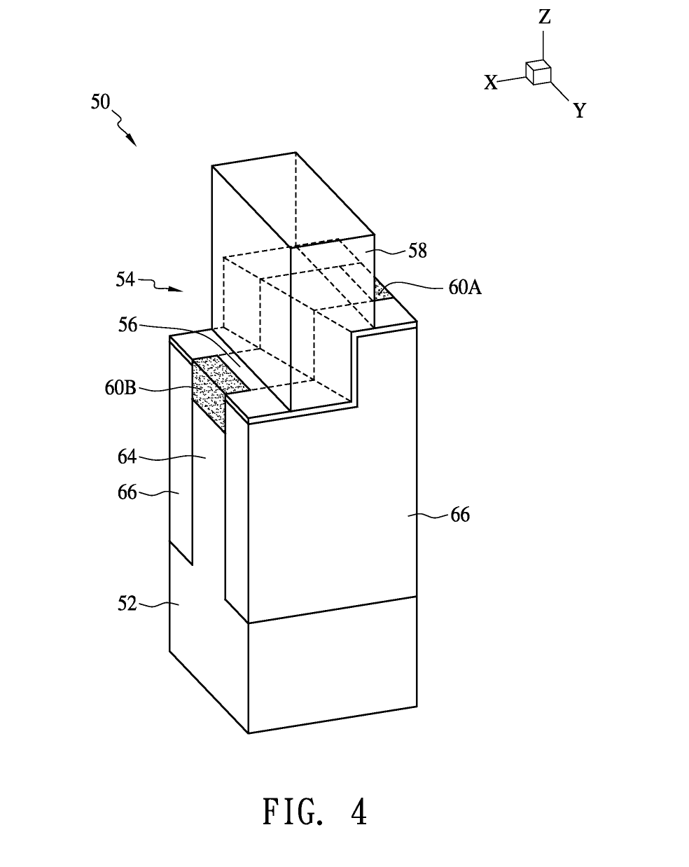

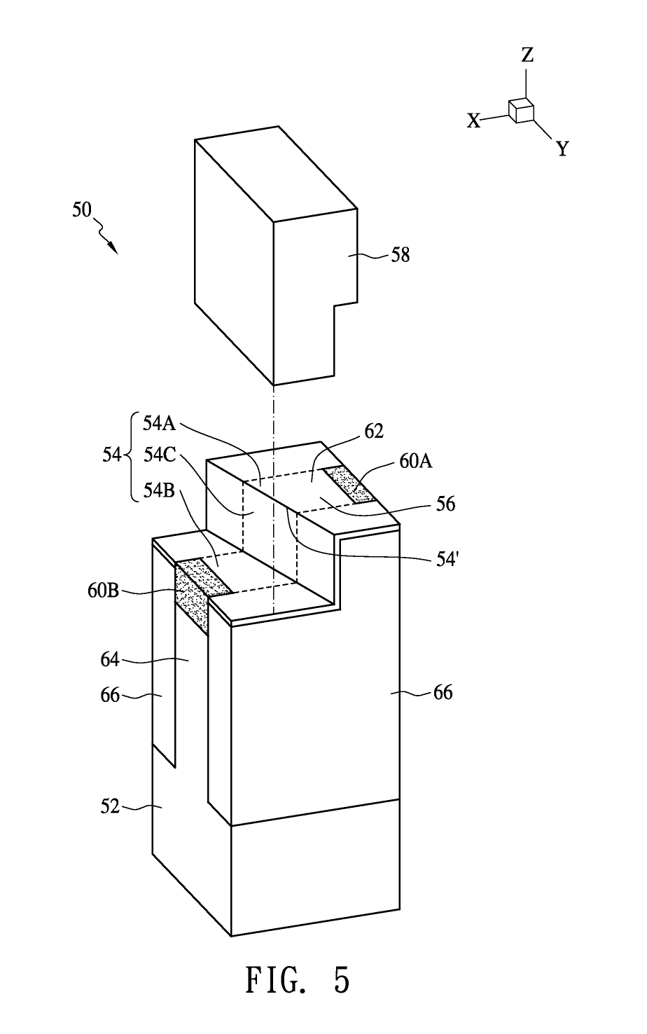

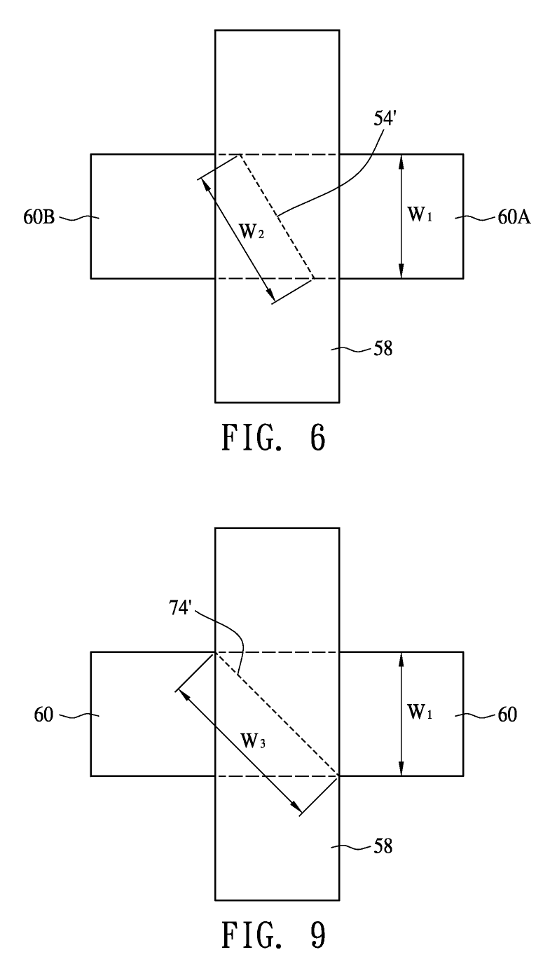

FIG. 4 to FIG. 6 illustrate a vertical transistor 50 according to one embodiment of the present invention, wherein FIG. 6 is a top view of the vertical transistor 50. The vertical transistor 50 comprises a substrate 52 such as a silicon substrate with a step structure 54, a gate oxide layer 56 positioned on the step structure 54, a conductive layer 58 positioned on the gate oxide layer 56, two doped regions 60A, 60B positioned in the substrate 52 at two sides of the step structure 54, and a carrier channel 62 positioned in the substrate 32 between the two doped regions 60A, 60B. In particular, the two doped regions 60A, 60B and the carrier channel 62 are positioned in an active area 64, which is surrounded by a shallow trench isolation 66.

The step structure 54 has an inclined edge 54′, and includes two trapezoid surfaces (non-rectangular surfaces) 54A, 54B and a rectangular surface 54C connecting the two trapezoid surfaces 54A, 54B. The trapezoid surface 54A connects the doped region 60A, the trapezoid surface 54B connects the doped region 60B, and the rectangular surface 54C is perpendicular to the two trapezoid surfaces 54A, 54B. The width (W1) of the carrier channel 62 at the step structure 54 (at the inclined edge 54′ of the trapezoid surface 54A) is larger than the width (W2) of the doped region 60A, as shown in FIG. 6. In other words, the width of the carrier channel 62 is increased from W2 (the width of the doped region 60A) to W1 (the width of the inclined edge 54′), which can increase the drain current and the driving ability of the vertical transistor 50.

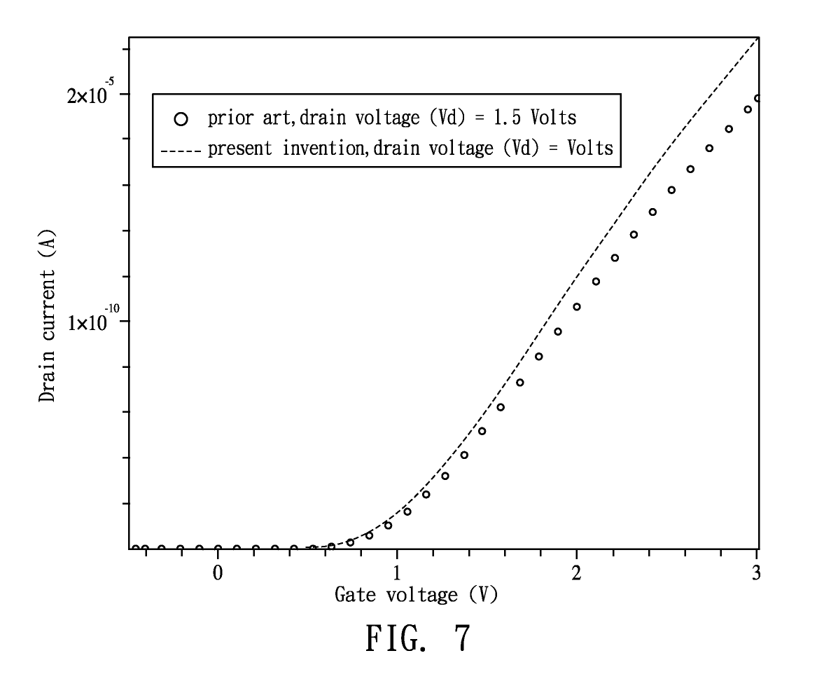

FIG. 7 compares the current-voltage property of the conventional vertical transistor 30 with that of the present vertical transistor 50. The drain current of the present vertical transistor 50 is larger than that of the conventional vertical transistor 30. Consequently, the step structure 54 with the inclined edge 54′ of the present vertical transistor 50 can actually increase the width of the carrier channel 62 such that the drain current and the driving ability of the present vertical transistor 50 can be increased.

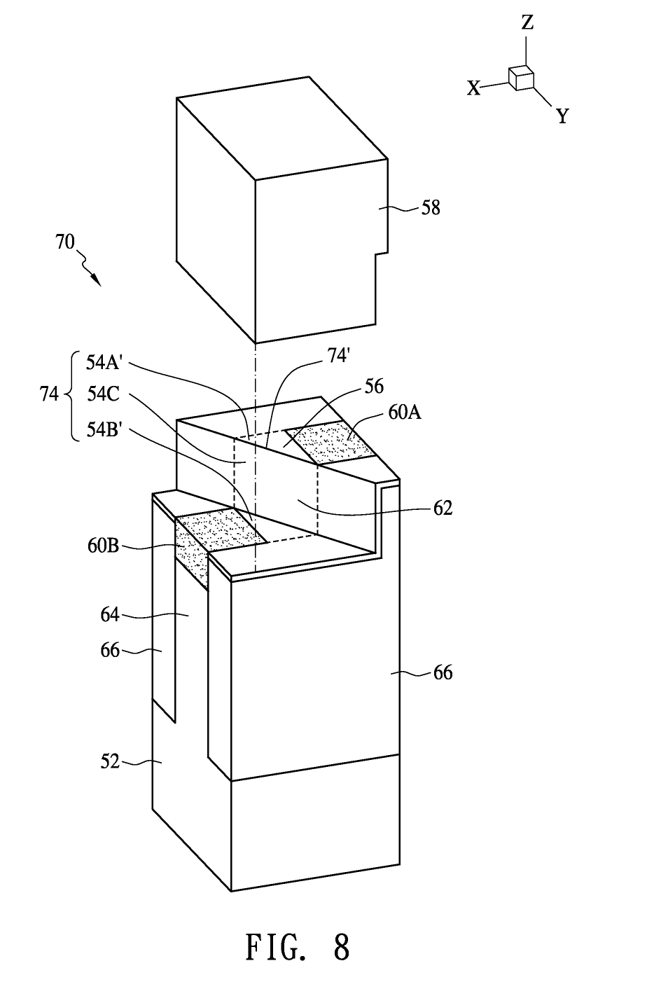

FIG. 8 and FIG. 9 illustrate a vertical transistor 70 according to another embodiment of the present invention, wherein FIG. 9 is a top view of the vertical transistor 70. The vertical transistor 70 has a step structure 74 with an inclined edge 74′, and includes two triangular surfaces (non-rectangular surfaces) 54A′, 54B′ and a rectangular surface 54C′ connecting the two triangular surfaces 54A′, 54B′. The triangular surface 54A′ connects the doped region 60A, the triangular surface 54B′ connects the doped region 60B, and the rectangular surface 54C′ is perpendicular to the two triangular surfaces 54A′, 54B′.

Compared with the vertical transistor 50 being able to increase the width of the carrier channel 62 from W1 to W2, the vertical transistor 70 can increase the width of the carrier channel 62 from W1 to W3, in which W3>W2>W1. In addition, the vertical transistors 50, 70 of the present invention can increase both the length and the width of the carrier channel 62, as compared with the conventional vertical transistor 30 which is able to increase the length of the carrier channel 42 but cannot increase the width of the carrier channel 42.

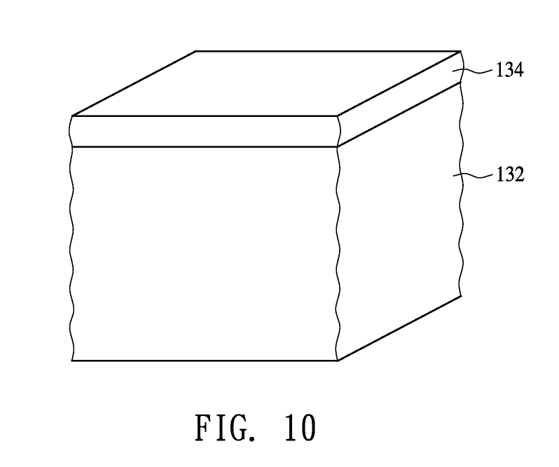

FIG. 10 to FIG. 16 illustrate a method for preparing a vertical transistor 100. A mask layer 134 is formed on a semiconductor substrate 132 such as a silicon substrate, and a predetermined portion of the mask layer 134 is removed by lithographic and etching processes, while the remaining mask layer 134′ covers a predetermined portion of the semiconductor substrate 132. Preferably, the mask layer 134 is made of dielectric material such as silicon oxide possessing a certain etching selectivity with respect to the silicon substrate. The mask layer 134′ is non-rectangular such as triangular with an inclined edge 134″. Subsequently, the mask layer 134′ is used as an etching mask in an etching process to remove a portion of the semiconductor substrate 132 not covered by the mask layer 134′ to form a first depression 136A, as shown in FIG. 11.

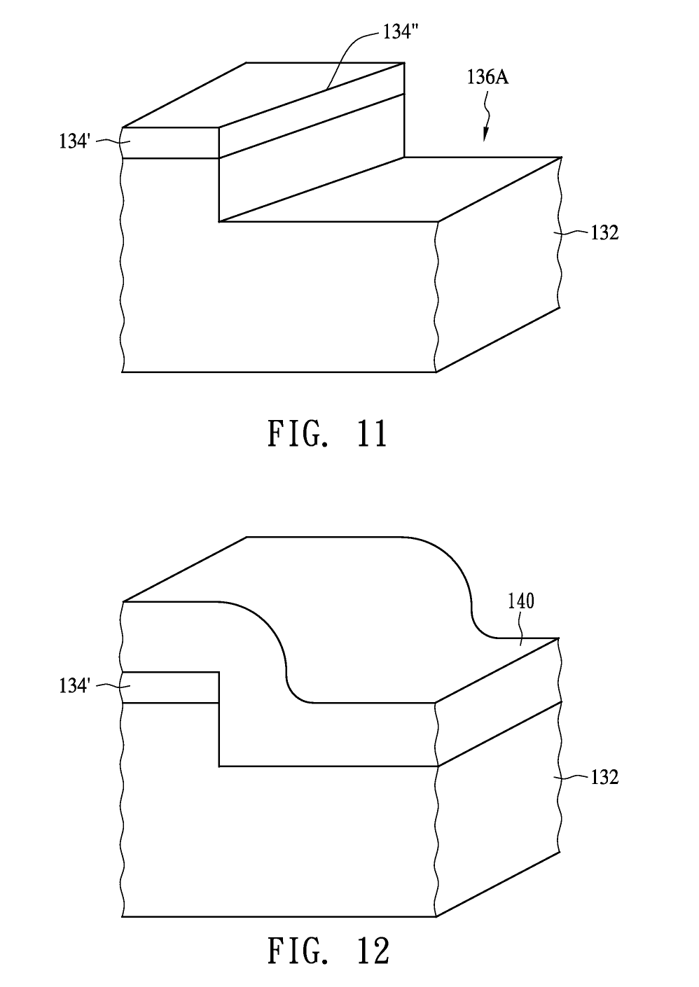

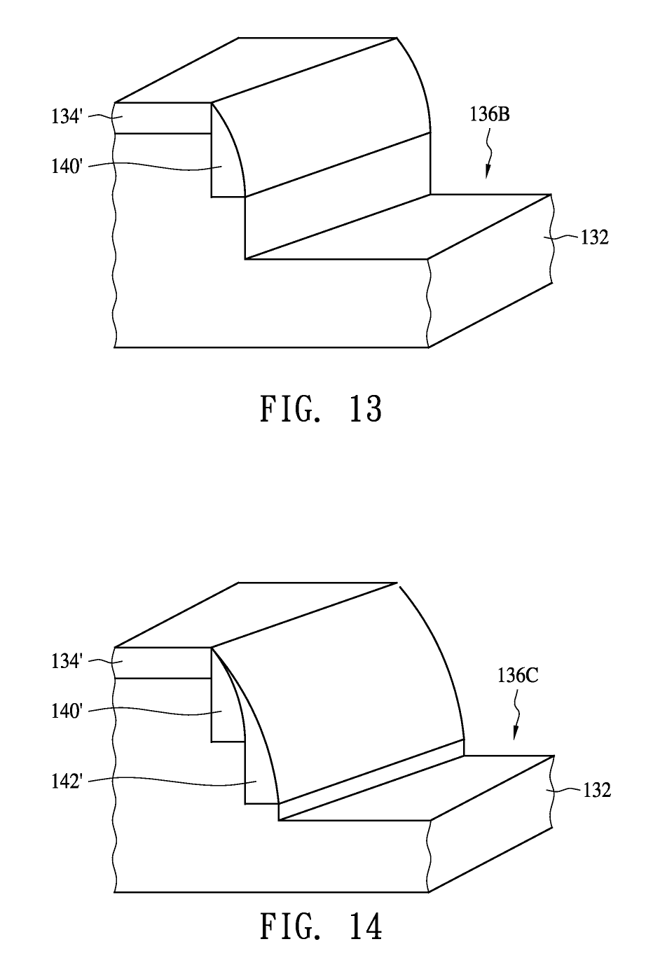

Referring to FIG. 12, a deposition process is performed to form a dielectric layer 140 on the semiconductor substrate 132, and an etching process is then performed to form a first spacer 140′ on the sidewall of the first depression 136A, wherein the first spacer 140′ is preferably made of dielectric material such as silicon oxide possessing a certain etching selectivity with respect to the silicon substrate. The first spacer 140′ and the mask layer 134′ are then used as an etching mask in an etching process to remove a portion of the semiconductor substrate 132 not covered by the etching mask down to a predetermined depth to form a second depression 136B, as shown in FIG. 13.

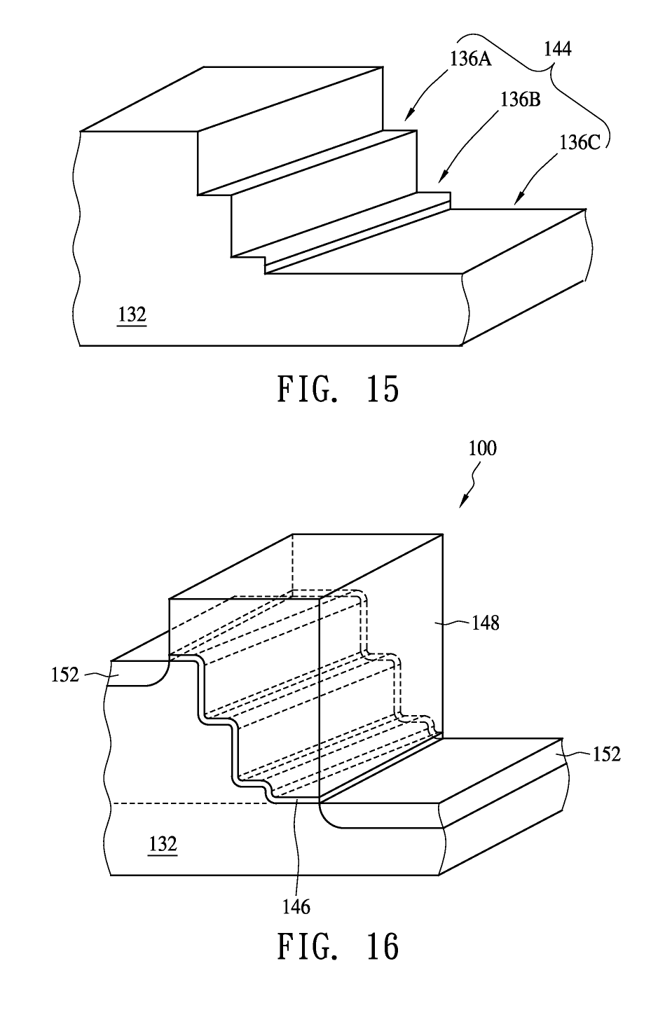

Referring to FIG. 14, a second spacer 142′ is formed on the sidewall of the second depression 136B by deposition and etching processes, and the mask layer 134′, the first spacer 140′ and the second spacer 142′ are then used as an etching mask in an etching process to remove a portion of the semiconductor substrate 132 not covered by the etching mask down to a predetermined depth to form a third depression 136C. Subsequently, the mask layer 134′, the first spacer 140′ and the second spacer 142′ are removed by an etching process to form a multi-step structure 144 consisting of the first depression 136A, the second depression 136B and the third depression 136C, as shown in FIG. 15.

Referring to FIG. 16, a thermal oxidation process is performed to form a gate oxide layer 146 on the surface of the multi-step structure 144, and a deposition process is then performed to form a conductive layer 148 on the gate oxide layer 146. Lithographic and etching processes are performed to remove a portion of the gate oxide layer 146 and the conductive layer 148, and the implanting process is performed by using the conductive layer 148 as the implanting mask to form two doped regions 152 serving the drain and the source in the semiconductor substrate 132 at two sides of the multi-step structure 144 to complete the vertical transistor 100.

The above-described embodiments of the present invention are intended to be illustrative only. Numerous alternative embodiments may be devised by those skilled in the art without departing from the scope of the following claims.

What is claimed is:

1. A vertical transistor, comprising:
a substrate having a step structure with an inclined edge;
two doped regions positioned in the substrate at the two sides of the step structure; and
a carrier channel positioned in the substrate between the two doped regions, wherein the width of the carrier channel at the inclined edge is larger than the width of the doped regions.

2. The vertical transistor of claim 1, wherein the step structure comprises two non-rectangular surfaces and a rectangular surface connecting the two non-rectangular surfaces.

3. The vertical transistor of claim 2, wherein the non-rectangular surfaces connect to the doped regions.

4. The vertical transistor of claim 2, wherein the rectangular surface is perpendicular to the non-rectangular surface.

5. The vertical transistor of claim 2, wherein the non-rectangular surfaces are triangular or trapezoid.

6. The vertical transistor of claim 1, further comprising a gate oxide layer positioned on the step structure.

7. The vertical transistor of claim 6, further comprising a conductive layer positioned on the gate oxide layer.

8. The vertical transistor of claim 1, wherein the two doped regions and the carrier channel are positioned in an active area.

9. The vertical transistor of claim 8, further comprising a shallow trench isolation surrounding the active area.

10. The vertical transistor of claim 1, wherein the step structure comprise a plurality of steps.

11. A method for preparing a vertical transistor, comprising the steps of:
forming a non-rectangular mask layer on a substrate;
etching the substrate by using the non-rectangular mask layer as an etching mask to form a step structure;
performing a thermal oxidation process to form a gate oxide layer on the step structure; and
forming a conductive layer on the gate oxide layer.

12. The method for preparing a vertical transistor of claim 11, wherein the step structure is formed by the steps of:
etching the substrate by using the non-rectangular mask layer as the etching mask to form a first depression;
forming a first spacer on a sidewall of the first depression; and
etching the substrate by using the non-rectangular mask layer and the first spacer as the etching mask to form a second depression.

13. The method for preparing a vertical transistor of claim 12, further comprising the steps of:
forming a second spacer on a sidewall of the second depression; and
etching the substrate by using the non-rectangular mask layer, the first spacer and the second spacer as the etching mask to form a third depression.

14. The method for preparing a vertical transistor of claim 12, wherein the mask layer is a photoresist layer or a dielectric layer.

15. The method for preparing a vertical transistor of claim 11, wherein the non-rectangular surfaces are triangular or trapezoid.
